(19) United States
(12) Patent Application Publication
(10) Pub. No.: US 2016/0058143 A1
(43) Pub. Date: Mar. 3, 2016

(54) PROTECTIVE COVER FOR ELECTRONIC DEVICE

(71) Applicant: HON HAI PRECISION INDUSTRY CO., LTD., New Taipei (TW)

(72) Inventor: LI-WEN TIEN, New Taipei (TW)

(21) Appl. No.: 14/751,866

(22) Filed: Jun. 26, 2015

(30) Foreign Application Priority Data
Aug. 29, 2014 (CN) 201410434179.1

(51) Int. Cl. A45C 11/00; H05K 5/02; H05K 5/03

(52) U.S. Cl. CPC A45C 11/00; H05K 5/03; H05K 5/0217

(57) ABSTRACT

A protective cover includes a first shell and a second shell. The first shell is configured to fit onto an electronic device, and includes a number of protrusions extending from a surface of the first shell. The second shell is configured to receive the first shell and the electronic device. The second shell defines a number of recesses for insertion of the protrusions of the first shell, and the first shell is fixed to the second shell by engagement of the recesses of the second shell and the protrusions of the first shell.

### CROSS-REFERENCE TO RELATED APPLICATIONS

This application claims priority to Chinese Patent Application No. 201410434179.1 filed on Aug. 29, 2014, the contents of which are incorporated by reference herein.

### FIELD

The subject matter herein generally relates to protective covers for receiving and protecting electronic devices.

### BACKGROUND

A protective cover is usually used for receiving and protecting an electronic device. However, existing protective covers are usually formed as a single rigid shell or a single soft shell having weak shockproof effect.

### BRIEF DESCRIPTION OF THE DRAWINGS

Implementations of the present disclosure will now be described, by way of example only, with reference to the attached figures.

FIG. 1 is an isometric view of an embodiment of a protective cover.

FIG. 2 is an exploded view of the protective cover of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features.

The present disclosure, including the accompanying drawings, is illustrated by way of examples and not by way of limitation. A definition that applies throughout this disclosure will now be presented. It should be noted that references to “an” or “one” embodiment in this disclosure are not necessarily to the same embodiment, and such references mean “at least one.”

Furthermore, the term “comprising” means “including, but not necessarily limited to”; it specifically indicates open-ended inclusion or membership in a so-described combination, group, series and the like.

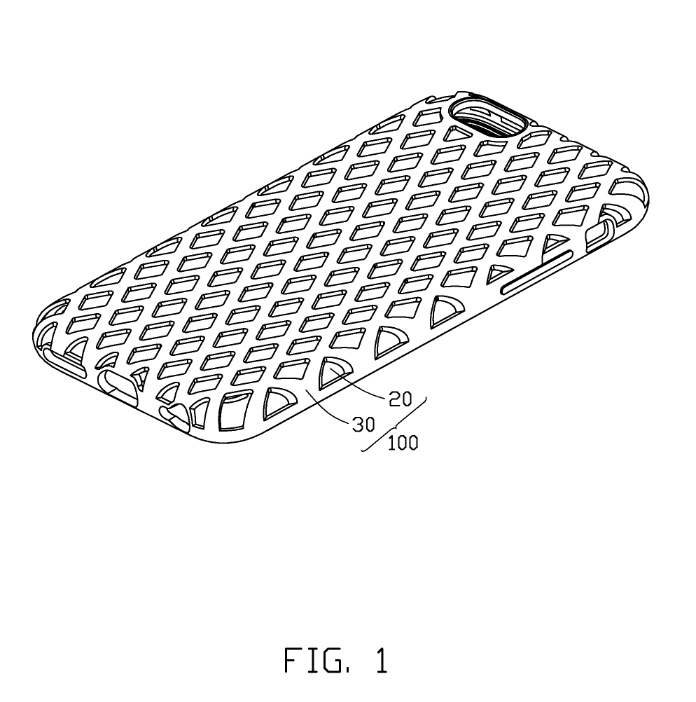

FIG. 1 is an isometric view of a protective cover. In at least one embodiment as shown in FIG. 1, a protective cover 100 is configured to receive and protect an electronic device (not shown). In the embodiment, the protective cover 100 includes a first shell 20 and a second shell 30. In the embodiment, the second shell 30 is configured to receive the first shell 20 and the electronic device.

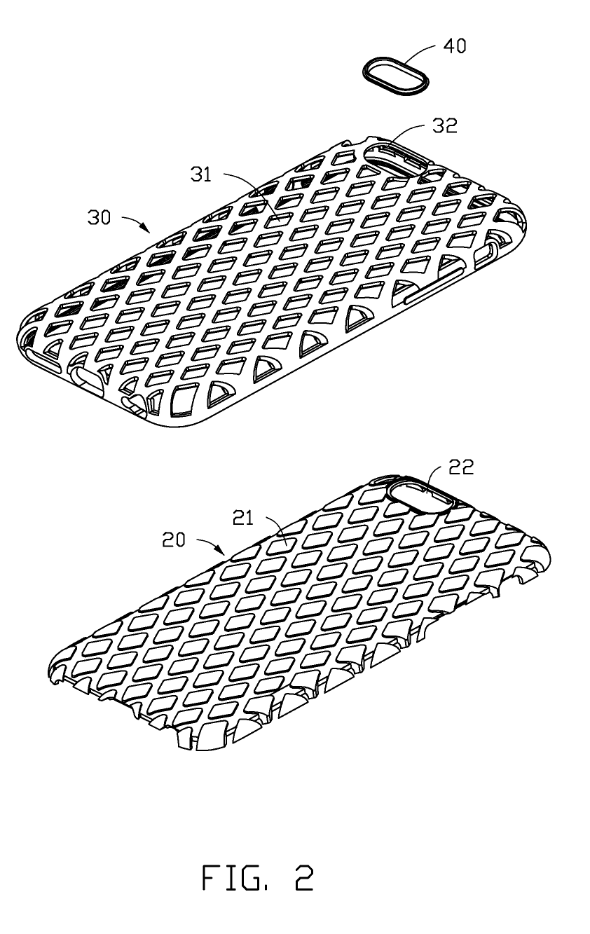

FIG. 2 illustrates in the embodiment, the first shell 20 includes a number of protrusions 21 extending from a surface of the first shell 20.

The second shell 30 defines a number of recesses 31 for insertion of the number of the protrusions 21, thus the first shell 20 can be fixed to the second shell 30 by engagement of the recesses 31 and the protrusions 21. With such structure, the protective cover 100 having two layers shell structures can provide a cushion to protect the electronic device against shock when the electronic device is dropped.

In the embodiment, the second shell 30 is made of flexible material, such as thermoplastic polyurethanes (TPU) material, to provide a good texture when held by the user and enhances the shockproof effect for the electronic device which is received in the protective cover 100. The first shell 20 can be made of rigid material or flexible material.

In the embodiment, the recesses 31 defined on the second shell 30 are through-holes, and each protrusion 21 has a height less than or equal to a depth of the corresponding recess 31.

In other embodiments, the recesses 31 defined on the second shell 30 can be blind holes which are defined on an internal surface of the second shell 30.

In the embodiment, the protrusions 21 are evenly distributed on the first shell 20. Correspondingly, the recesses 31 are evenly distributed on the second shell 30.

In other embodiments, the protrusions 21 can be unevenly distributed on the first shell 20. Correspondingly, the recesses 31 can be unevenly distributed on the second shell 30.

In the embodiment, each protrusion 21 and a corresponding recess 31 have a diamond shape. In other embodiments, each protrusion 21 and a corresponding recess 31 has a round shape, a square shape, a rectangle shape, or an oval shape, to add pleasing esthetic appearance to the protective cover 100.

In the embodiment, the first shell 20 defines at least one first through-hole 22, and the second shell 30 defines at least one second through-hole 32 spatially corresponding to the first through-hole 22. The first through-hole 22 and the spatially corresponding second through-hole 32 are configured to expose a function button, such as a volume button or a power button, a function hole, such as a headphone jack or a Universal Serial Bus (USB) port, or a camera of the electronic device which is received in the protective cover 100.

In the embodiment, a flexible ring 40 is attached to the first through-hole 22 and the spatially corresponding second through-hole 32 which is configured to expose the camera of the electronic device.

The embodiments shown and described above are only examples. Even though numerous characteristics and advantages of the present technology have been set forth in the foregoing description, together with details of the structure and function of the present disclosure, the disclosure is illustrative only, and changes can be made in the detail, including in particular the matters of shape, size, and arrangement of parts within the principles of the present disclosure, up to and including the full extent established by the broad general meaning of the terms used in the claims.

What is claimed is:

1. A protective cover comprising:
a first shell configured to fit onto an electronic device, and comprising a plurality of protrusions extending from a surface of the first shell; and
a second shell configured to receive the first shell and the electronic device, the second shell defining a plurality of recesses for insertion of the plurality of the protrusions of the first shell, the first shell being fixed to the second shell by engagement of the recesses of the second shell and the protrusions of the first shell.

2. The protective cover as described in claim 1, wherein the second shell is made of flexible material.

3. The protective cover as described in claim 2, wherein the second shell is made of thermoplastic polyurethanes material.

4. The protective cover as described in claim 1, wherein the recesses defined on the second shell are through-holes, and each protrusion has a height less than or equal to a depth of the corresponding recess.

5. The protective cover as described in claim 1, wherein the recesses defined on the second shell are blind holes which are defined on an internal surface of the second shell.

6. The protective cover as described in claim 1, wherein the plurality of protrusions are evenly distributed on the first shell, and the plurality of recesses are evenly distributed on the second shell.

7. The protective cover as described in claim 1, wherein the plurality of protrusions are unevenly distributed on the first shell, and the plurality of recesses are unevenly distributed on the second shell.

8. The protective cover as described in claim 1, wherein each protrusion and a corresponding recess have an appearance which is selected from a group consisting of a diamond shape, a round shape, a square shape, a rectangle shape, and an oval shape.

9. The protective cover as described in claim 1, wherein the first shell defines at least one first through-hole, and the second shell defines at least one second through-hole spatially corresponding to the first through-hole, the first through-hole and the spatially corresponding second through-hole are configured to expose a function button, a function hole, or a camera of the electronic device which is received in the protective cover.

10. A protective cover for an electronic device having a camera and buttons, comprising:
a first shell having a plurality of protrusions extending from an outer surface of the first shell, and configured to fit onto the electronic device; and
a second shell configured to receive the first shell and the electronic device, the second shell having a plurality of first recesses and/or holes to mate with the protrusions of the first shell; and
the first and second shells having a plurality of overlapping second recesses and/or holes to define pathways through the cover to allow for access to the buttons and camera through the cover;
wherein the first shell is fixed to the second shell by engagement of the protrusions of the first shell and first recesses and/or holes of the second shell.

11. The protective cover as described in claim 10, wherein the second shell is made of flexible material.

12. The protective cover as described in claim 10, wherein the first shell is made of rigid material.
